(19) United States
(12) Patent Application Publication
(10) Pub. No.: US 2021/0071308 A1
(43) Pub. Date: Mar. 11, 2021

(54) SELECTIVE SURFACE FINISHING FOR CORROSION INHIBITION VIA CHEMICAL VAPOR DEPOSITION

(71) Applicant: University of North Texas, Denton, TX (US)

(72) Inventors: Oliver Ming-Ren Chyan, Denton, TX (US); Muthappan Asokan, Denton, TX (US)

(21) Appl. No.: 17/015,046

(22) Filed: Sep. 8, 2020

Related U.S. Application Data
(60) Provisional application No. 62/897,942, filed on Sep. 9, 2019.

(51) Int. Cl. C23F 11/02; C23C 16/52; C23C 16/02; C23C 16/46; C23C 16/56

(52) U.S. Cl. CPC C23F 11/02; C23C 16/52; C23C 16/56; C23C 16/46; C23C 16/0209

(57) ABSTRACT

A versatile, thermally stable and economically effective corrosion inhibition treatment for copper (Cu) metal and selected metals surface through a single step chemical vapor deposition (CVD) of selected inhibitor compounds at temperatures as low as 100-200° C. is described in this invention. The resulting CVD deposited inhibition coating is thermally stable to 300° C. and protects Cu and selected metals from active corrosion in various technologically important operational environments. The selective coating for copper metal is achieved by controlling the chemistry of bonding between the Copper metal surface and inhibitor material used. The technique can be accomplished by using one or more inhibitors separately or in combination in order to create an all-terrain stable & robust corrosion prevention coating for copper metal.

### CROSS-REFERENCE TO RELATED APPLICATIONS

The present application claims priority to U.S. Provisional Patent Application No. 62/897,942 filed Sep. 9, 2019 and entitled “SELECTIVE SURFACE FINISHING FOR CORROSION INHIBITION VIA CHEMICAL VAPOR DEPOSITION,” the disclosure of which is incorporated by reference herein in its entirety.

### TECHNICAL FIELD

The present disclosure generally relates to the selective surface treatment of metal to promote corrosion inhibition through formation of a metal-inhibitor complex layer on Copper surface via Chemical Vapor Deposition.

### BACKGROUND

Copper (Cu) being the fifth most abundant material in earth's crust, is one of the most commonly used metals among a wide spectrum of industrial applications. For example, copper is frequently used in wires, metal sheets, heat exchanger parts, electrical and electronic applications, marine industries, as well as many other industrial applications. With a better conductivity and mechanical strength than both gold (Au) and aluminum (Al), copper has slowly replaced gold as the preferred interconnect metallization material in the microelectronic industry. Over the past three decades the role of copper in the microelectronic industry has been increasing exponentially (e.g., Cu metallization, Cu bonding wires, Cu re-distribution layer patterning, and the like). For wafer level packaging, Cu has been the preferred material for Re-Distribution Layer (RDL) due to its easily patternable capacity. However, corrosion-related failures pose a major threat to device reliability and copper corrosion is one of the main sources of this threat. The emerging trend of wearable electronics and automated vehicles also imposes new, more stringent reliability requirements (even down to 0 parts per billion (ppb) failure levels in automobile electronics) to ensure corrosion protection from sweat/mud/rain in all-terrain non-stop usage conditions. In addition, the versatile use of copper in the microelectronic industry at the microscopic level means that corrosion reliability of copper is more relevant now than ever before.

In areas outside of the microelectronic industry, copper corrosion may lead to detrimental material loss and process sabotage in many applications, such as heat transfer components, and high power transmission line copper parts, off shore electrical parts involving copper and alloyed copper, and the like. In addition, the emergence of electric vehicles in the automobile industry demands an increasing usage of copper in automobile and battery parts where copper is more likely to be exposed to harsh environments. As a result, corrosion reliability plays a critical factor in determining the commercial success of these parts, as it becomes a matter of life and death.

Despite having a passivating oxide layer on the surface, copper metal is not entirely corrosion resistant. Various aggressive environments containing chloride, sulfide, persulfate, citrate, or similar compounds may cause the metal surface to become susceptible to corrosion. Also, copper is one of the most commonly alloyed metals. Depending on the composition of the alloy(s), copper can act as anode or cathode within the alloy compound itself, which may promote corrosion. Previous approaches propose applying an inhibitor coating by including inhibitor compounds directly in a test solution to achieve corrosion protection. A considerable number of previous approaches include one or more corrosion protection agents containing nitrogen, sulfur, or oxygen moieties. While a wide range of inhibitor compounds have been proven effective for corrosion protection, the method(s) used to apply inhibitor compounds, whether via a solution or volatile vapor phase application, severely limits the use of inhibitor compounds across variable corrosive environments relevant to modern technological applications, as discussed above.

Also, copper, being a good conductor of electricity, is often used in high power and high temperature applications and in many cases, addition of inhibitor compounds to the solution may not be practically applicable as the corrosion process may not always be limited to a liquid phase and the coating might not be strong enough to survive high temperature and high bias corrosive environments. In some of the cases, Volatile Corrosion Inhibitor (VCI) compounds have been used to promote corrosion protection. However, even when VCIs are used to inhibit corrosion (e.g., in a vapor phase), a carrier medium (e.g., a polymeric packaging film, wrapping Kraft paper, or a similar carrier material) is required. There have been reports of cases where carriers like glycols, and wax can themselves cause corrosive effects on the copper material(s) to be protected. Also, one of the key problems of VCI applications is the reversibility of inhibitor adsorption on metal surfaces, which presents a major limitation since such applications may only be useful in closed space applications like shipping containers, packaged environments, and the like.

It has been difficult to realize large commercialized usage of previous techniques for application of corrosion inhibition coatings. Thus, there is a need for a versatile, easy to apply, all-terrain compatible, and environmentally stable preventive coating for copper metal. The process should be economically and environmentally viable and be able to create a stable corrosion inhibition coating layer on top of copper with high degree of reproducibility and uniformity in coating. The process should also be scalable in order to support large-scale operations, which acts as the key factor for promoting the commercial success of the coating process.

### SUMMARY

The present disclosure provides systems and methods for applying corrosion resistant coatings to mitigate Cu corrosion in various applications as Cu wire bonding, wafer level packaging, redistribution layer in microelectronics, Cu metallic components in applications like heat exchangers, high power transmission, automobile parts etc. In an aspect, chemical vapor deposition (CVD) techniques may be used to apply corrosion inhibiting layers that improve the resistance to copper corrosion. For example, a copper metal device may be placed within a CVD coating chamber simultaneously with an amount of one or more selected corrosion inhibiting compounds and the chamber is heated to a process temperature that depends on the inhibiting compound used. The particular corrosion inhibiting compound(s) utilized may be selected based on the composition of the copper metal device and other factors, such as the type of corrosive agents to be mitigated by the inhibiting layer formed through the CVD process. Operational parameters of the CVD process, such as the duration of the coating process, the amount of the selected corrosion inhibiting compounds placed within the chamber, the temperature, or other parameters, may be used to control the thickness of the formed corrosion inhibiting coating layer. After the CVD coating process is completed, the copper metal device with the corrosion inhibiting layer deposited thereon may be removed from the CVD coating chamber and subjected to further processing, such as packaging, post-treatment, annealing, or other processes. Embodiments disclosed herein facilitate reuse of portions of the corrosion inhibiting compounds remaining after the CVD process has completed. For example, the corrosion-inhibiting compounds may be transformed into a vapor state during the CVD process and then re-condensed within the CVD coating chamber after removal of the copper metal device. The re-condensed portion of the corrosion-inhibiting compound may then be utilized in a second CVD coating process to apply a corrosion inhibiting layer to a second copper metal device. This reduces the overall cost of the process to apply corrosion inhibiting layers and enables efficient use of materials during the coating process.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features that are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawings, in which:

FIG. 1 is a block diagram illustrating exemplary aspects of a one-step process for applying inhibitor coatings to a metal surface in accordance with the present disclosure;

FIG. 2 illustrates three different configurations of a metal surface utilized to conduct testing of inhibitor coatings applied in accordance with the present disclosure;

FIG. 3A is a diagram illustrating an experimental setup utilized to test the inhibitor coating on a copper wire formed in accordance with the present disclosure;

FIG. 3B is a diagram illustrating test results associated with testing the corrosion resistance of copper wire (used in IC packaging for copper wire bonded devices) after undergoing a CVD treatment in accordance with the present disclosure;

FIG. 4 is another diagram illustrating test results associated with corrosion resistance of inhibitor coatings formed through the methods disclosed herein on copper bumps used in flip chip wafer level packaging;

FIG. 5 is a diagram illustrating electrochemical test results associated with corrosion prevention performance of an inhibitor coating applied on a flat copper metal surface using the techniques disclosed herein;

FIG. 6 is a diagram illustrating test results associated with the performance of an inhibitor coating applied on Cu surface in a Cu RDL using the techniques disclosed herein;

FIG. 7 is a chart illustrating the change in surface contact angle of water on copper metal surface before and after the application of inhibitor coating created using the techniques disclosed herein;

FIG. 8 is a diagram illustrating results of infrared spectra tests illustrating the thermal stability of the inhibitor coating applied using techniques disclosed herein (the infrared spectra was recorded before and after the exposure of coating to 260° C. for a duration of 25 minutes);

FIG. 9 is a chart illustrating the various stages of thermal decomposition analysis of the applied inhibitor coating using the Thermal Gravimetric Analysis technique;

FIG. 10A is a diagram illustrating results of a series of infrared spectra tests illustrating structural integrity of inhibitor compounds re-condensed and collected after each CVD run via recycling techniques disclosed herein;

FIG. 10B is another infrared spectra tests illustrating the structural robustness of inhibitor compounds re-condensed and collected after each CVD run via recycling techniques disclosed herein;

FIG. 11 is a diagram illustrating plots of infrared spectra observed while testing the affinity of the selected inhibitor compound in vapor phase to different metal surfaces, when exposed at the same time;

FIG. 12 is a diagram illustrating plots of infrared spectra observed during testing of metal surfaces after coating and the coating is subjected to infrared analysis before and after being immersed in solution;

FIG. 13 is a flow diagram illustrating aspects of a method for applying a corrosion inhibitor layer to a metal surface in accordance with the present disclosure; and

FIG. 14 is a flow diagram illustrating aspects of another method for applying a corrosion inhibitor layer to a metal surface in accordance with aspects of the present disclosure.

### DETAILED DESCRIPTION

Various features and advantageous details are explained more fully with reference to the non-limiting embodiments that are illustrated in the accompanying drawings and detailed in the following description. Descriptions of well-known starting materials, processing techniques, components, and equipment are omitted so as not to unnecessarily obscure the invention in detail. It should be understood, however, that the detailed description and the specific examples, while indicating embodiments of the invention, are given by way of illustration only, and not by way of limitation. Various substitutions, modifications, additions, and/or rearrangements within the spirit and/or scope of the underlying inventive concept will become apparent to those skilled in the art from this disclosure.

In the description that follows, improved processes for using chemical vapor deposition to deposit a layer of one or more inhibitor compounds on a metal surface to create a corrosion-inhibiting layer on the metal surface are disclosed. The deposited inhibitor coating may form a composite layer on top of the metal surface to inhibit corrosion. The disclosed techniques may be utilized with various inhibitor compounds that provide good corrosion protection to metal surfaces, such as Cu metal surfaces, and may facilitate a single-step process for applying such corrosion inhibiting compounds.

During application of inhibitor compounds, one of several advantages is that the inhibitors can bind to the metallic surface via formation of a strong chemical bond. Copper metal by nature has a mixture of semi-passivating Cu¹⁺ and Cu²⁺ oxide layers on the surface. As described below, the techniques disclosed herein may enable fine adjustment of a Cu surface composition while promoting favorable interaction between the metal surfaces and the applied inhibitor compounds. In addition to Cu, the inhibitor compounds may also protect other metal surfaces, such as Fe, Ni, Co, Zn, and steel from corrosion.

To facilitate the one-step inhibitor deposition techniques disclosed herein, chemical vapor deposition processes may be performed in an environment where atmospheric conditions are controlled to form a corrosion inhibiting layer on the metal surface. The direct application of inhibitors in the vapor phase has been carried out once before and the scope of that report lies within the context of Cu interconnect protection after chemical mechanical polishing. IPA was used as a carrier gas to transport inhibitor compound from one chamber to treat Cu interconnects on a silicon wafer after finishing chemical mechanical polishing in a separate chamber. In the invention described here, the deposition of inhibitor compounds can be carried out at much lower temperatures (100-150° C.) than the previously reported 150-300° C., and without the need of a carrier gas. By just heating the copper with the chosen inhibitor compound at 100-150° C., a uniform layer of inhibitor coating, chemically bonded to the Cu metal surface, can be formed on the surface of copper. This method of formation of metal-inhibitor composite coating has its own specific beneficial properties that differentiates the current application methods from previously reported ones.

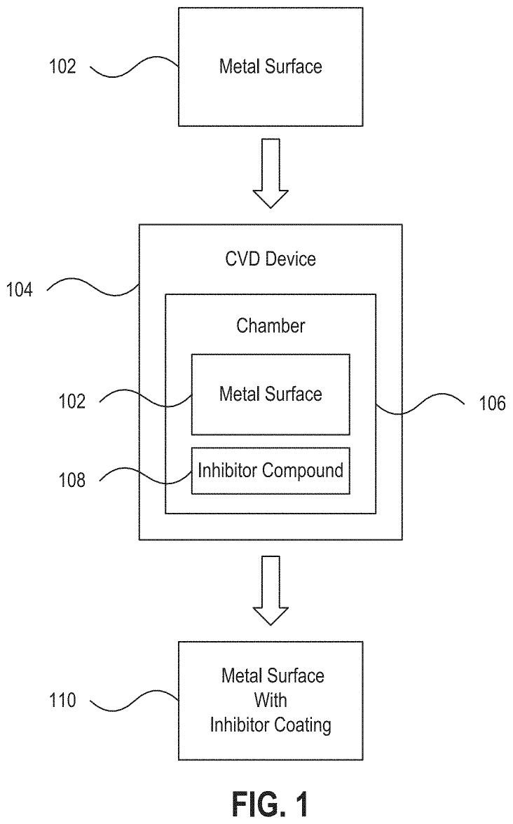

Referring to FIG. 1, a block diagram illustrating exemplary aspects of a one-step process for applying inhibitor coatings to a bonded metal surface in accordance with the present disclosure is shown. In FIG. 1, a Cu metal surface 102 and a chemical vapor deposition device 104 are shown. The Cu metal surface 102 may include one or more metals, as described above. For example, Cu metal surface 102 may include Cu alone, Cu alloys or Cu in contact with other metals, such as Al, nickel (Ni), iron (Fe), cobalt (Co), zinc (Zn), palladium (Pd), Au, or silver (Ag). It is noted that these exemplary metal surfaces have been provided for purposes of illustration, rather than by way of limitation and that the techniques disclosed. The inhibitor compounds 108 to be applied to the Cu metal surface 102 may be selected based on the particular characteristics of the Cu metal surface 102. For example, one or more inhibitor compounds may be better suited for application to certain types of bonded metal surfaces (e.g., Cu wires bonded to Al bonding pads) than other types of inhibitor compounds, which may be better suited for other types of bonded metal surfaces (e.g., Cu patterns on dielectric parts).

Once the appropriate inhibitor compounds 108 have been selected, the Cu metal surface 102 and the selected inhibitor compounds 108 may be placed within a chamber 106 of the chemical vapor deposition device 104. Once placed in the chamber 106, the inhibitor compounds 108 and the Cu metal surface 102 may be heated to an appropriate temperature. The particular temperature to which the inhibitor compound 108 and the Cu metal surface 102 are heated may be determined, at least in part, based on the selected inhibitor compounds. The inhibitor compounds 108 may transition to a vapor phase during heating, causing the Cu metal surface 102 to be coated with a layer of the inhibitor compounds 108, resulting in a Cu metal surface with an inhibitor coating 110.

As shown above, because the inhibitor compound 108 and the Cu metal surface 102 are simultaneously heated within the chamber 106, the application of the inhibitor coating may be accomplished in a single step. To enhance and aid in the coating of the Cu metal surface 102, the Cu metal surface 102 may be positioned in such a way that it receives maximum exposure to the vaporized inhibitor compound 108. For example, the Cu metal surface 102 may be placed in an inverted configuration with the bonding locations (e.g., Cu bonding locations) facing the inhibitor compound 108 so that the vapors formed during vaporization of the inhibitor compound 108 will make direct, easy contact with Cu surface. Such an orientation may enable maximum interaction of the vaporized inhibitor compound with the Cu metal surface 102. This promotes the formation of a uniform layer of the inhibitor compound bonded to the Cu metal surface 102.

During the process of depositing the inhibitor coating, the atmosphere within the chamber 106 may be controlled to have one or more characteristics. For example, the atmosphere may be controlled to an ambient atmosphere, an oxygenated atmosphere, a nitrogen-rich atmosphere, a reducing atmosphere of N₂/H₂ gas, or some other atmospheric makeup. The particular atmospheric control within the chamber 106 depends on the particular inhibitor compound 108 and metal surface 102 to be coated. For example, the atmosphere control required for coating the same Cu metal surface 102 can differ between when two different inhibitor compounds are used. It is noted that controlling the atmosphere within the chamber 106 may be utilized in addition to, or as an alternative to, placing the metal surface 102 in a position to promote and aid application of the inhibitor coating.

The thickness of the inhibitor coating may be controlled by varying parameters of the chemical vapor deposition process, such as the temperature under which deposition process is carried out, the amount of the inhibitor compound(s) 108 loaded into the chamber 106, and the amount of time that the metal surface 102 is exposed to the inhibitor compound vapors. For example, larger quantities or amounts of the inhibitor compound(s) 108 being loaded into the chamber 106 may result in a thicker inhibiting layer. In some cases because of thicker coatings, the metal may be consumed to a certain extent.

In an aspect, the metal surface 102 may be pre-treated prior to applying the coating. For example, the metal surface 102 may be annealed in H₂ or in N₂/H₂ forming gas atmosphere prior to exposure to the coating process. Alternatively, the metal surface 102 may be treated with an acid treatment, base treatment, a plasma treatment, or another pretreatment to fine tune portions of the metal surface 102 to promote the bonding of selected inhibitor compound(s) 108 to the metal surface 102. Subsequent to the annealing process, the metal surface 102 may be treated using the process described above with respect to FIG. 1.

In another exemplary aspect, the process described above where the metal surface 102 is annealed prior to the chemical vapor deposition process may be performed, and subsequently followed by a post annealing process. The post annealing process may be performed at a temperature between 150-300° C. The post annealing process may result in a uniform inhibitor composite coating being applied to the metal surface 102, which may improve the corrosion resistance.

In an additional or alternative aspect, the metal surface 102 may be introduced into the chamber 106, which already contains the chosen inhibitor compound 108 in its vapor phase in order to facilitate the interaction between the inhibitor compound(s) 108 and the metal surface 102. This may promote the interaction between the vapors of inhibitor compound 108 and the specific species of metal/metal ion on the surface of the metal to be coated 102.

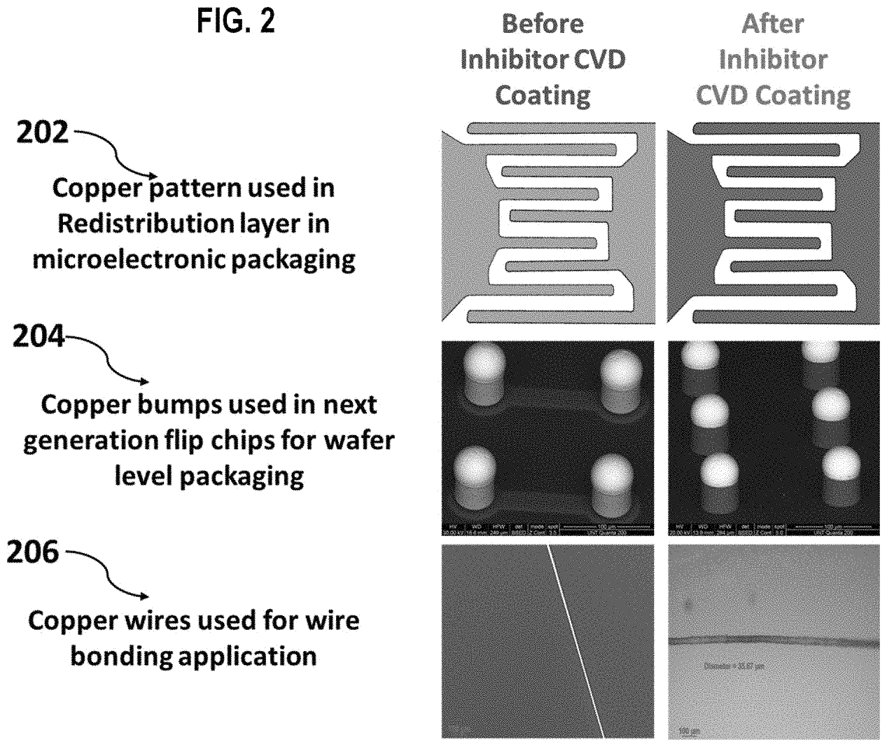

To demonstrate the corrosion inhibition efficiency of the coating formed through the single step process described and illustrated with respect to FIG. 1, three different forms of copper samples were tested using the CVD treatment described above. As shown in FIG. 2, the three tested Cu samples included: (1) Cu RDL patterns, shown at 202, (used for advanced packaging applications where electrochemical migration or corrosion of Cu is prevalent); (2) 50 μm thick Cu bumps (used for advanced flip chips wafer level packaging applications) shown at 204; and (3) 30 μm thick Cu wires (used in wire-bonding and other electrical and micro-electronic applications, shown at 206).

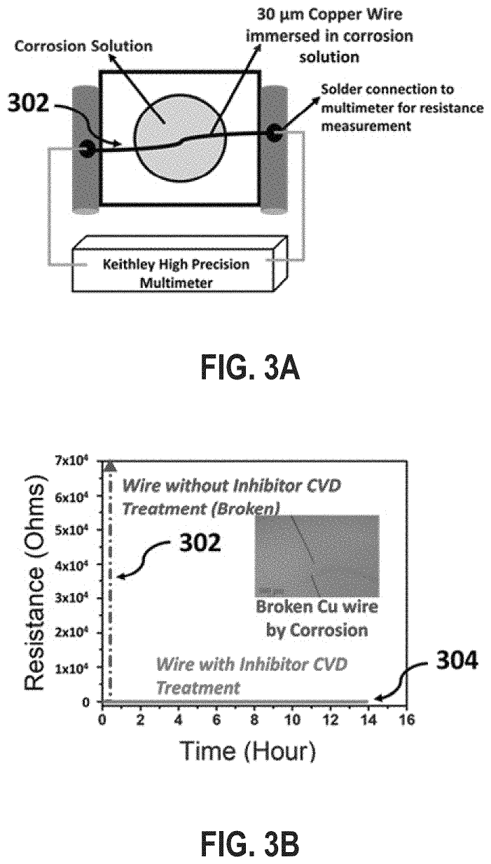

Referring to FIG. 3A, a diagram illustrating an experimental setup utilized to test a coating formed in accordance with the present disclosure is shown. During testing, corrosion screening of the Cu samples was carried out in a corrosion solution (e.g., 0.05 M ammonium persulfate solution at acidic pH conditions). The test corrosion solution was chosen due to its ability to oxidize copper (ammonium persulfate is one of the strongest oxidizing agents known for oxidizing and etching copper). Using this harsh solution for corrosion testing allows exposure to and also tests the inhibition efficiency of the Cu metal in the harshest possible environment and also accelerates the corrosion testing process. The CVD coating provided an excellent resistance to corrosion, as shown by the resistance measurements depicted in FIG. 3B. As shown in FIG. 3B the un-treated Cu wire 302 was rapidly corroded and broke 40 minutes after immersion in the ammonium persulfate corrosion solution, as indicated in FIG. 3B. In contrast, the CVD coated Cu wire 304 resisted the corrosion attack in the same solution over 14 hours, confirming excellent corrosion inhibition of the coating formed via CVD treatment disclosed herein.

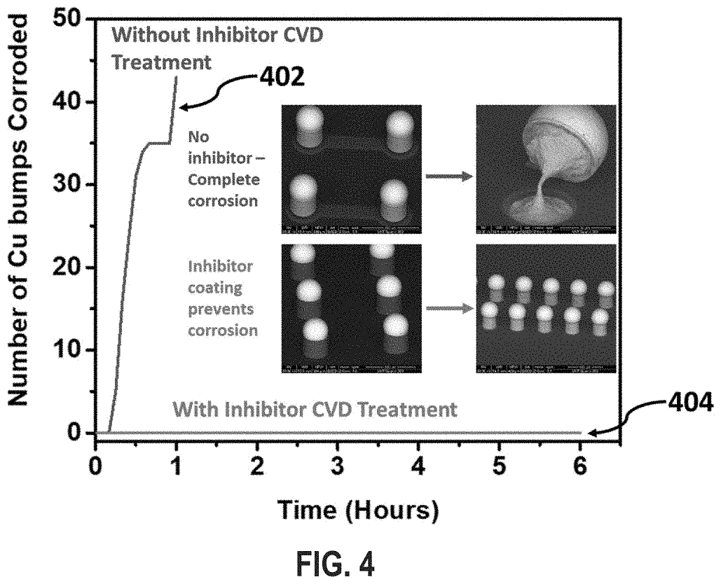

As shown in FIG. 4, 50 μm Cu bumps (similar to the Cu bumps illustrated in FIG. 2 at 204), which are commonly used in wafer level packaging applications, were exposed to a harsh environment (at alkaline pH) containing 0.05 M ammonium persulfate solution. The bumps after going through protective CVD coating process were able to resist the Cu corrosion for over 6 hours in this harsh environment, as indicated at 404. On the other hand, the Cu bump device without any protective coating started showing signs of corrosion as soon as 14 minutes and the entirety of bumps were seen to corrode in just one hour, as shown at 402.

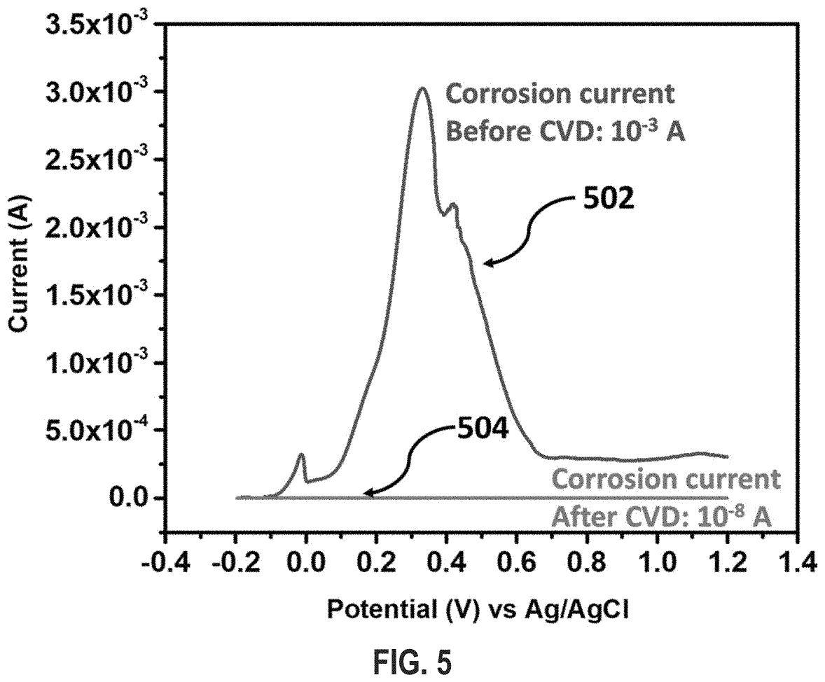

Referring to FIG. 5, a diagram illustrating electrochemical test results associated with performance of an inhibitor coating applied on a flat copper metal surface using the techniques disclosed herein is shown. The linear sweep voltammetry analysis of the inhibition coating on a Cu surface (FIG. 5) shows that the inhibitor coating was able to reduce the Cu corrosion current under positive potential biased (504 in FIG. 5) by a factor of 10⁵ times, in the presence of a strong halide ion contaminated environment (e.g., 3.5 wt. % sodium chloride (NaCl) solution), in comparison with a Cu surface that is not coated with the inhibitor compound (502 in FIG. 5).

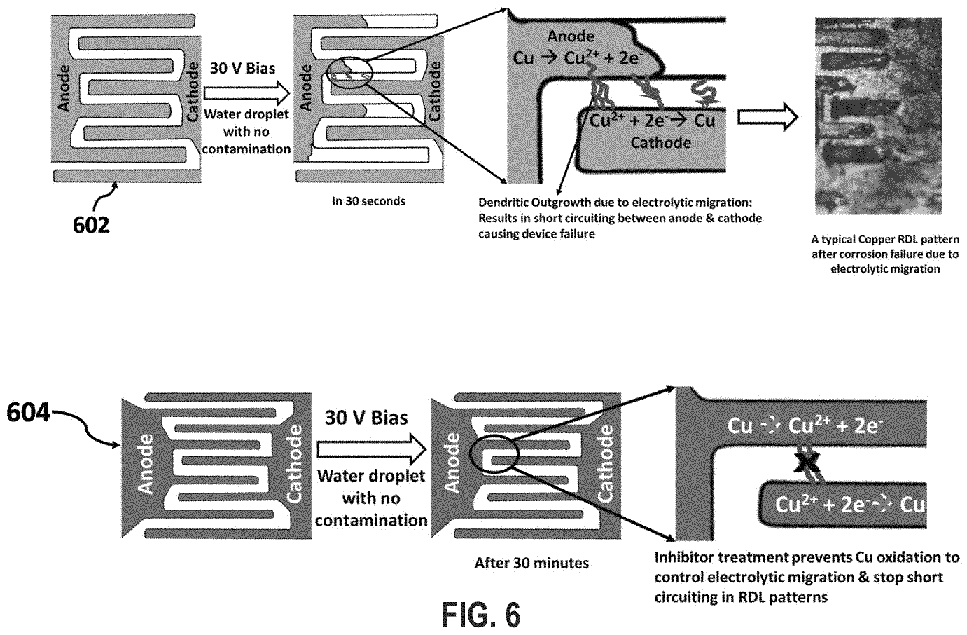

The third set of samples used for testing the coating formed via CVD included Cu RDL patterns used in wafer level packaging. In these types of Cu devices, the RDL pattern suffers catastrophic defects due to electrolytic migration in the presence of moisture and contaminants. For this test, the CVD coating was targeted to selectively coat the Cu patterns avoiding the interlaying dielectric layers of the device. The corrosion was tested with an uncontaminated water droplet added to the surface of the Cu patterns under an applied voltage bias of 10 V-30 V. The corrosion screening result is depicted in FIGS. 6A and 6B. FIG. 6A shows Cu patterns without the inhibitor treatment 602, which experienced short-circuiting instantaneously and failure time was less than a minute. The increasing tight spacing (<10 micron) between Cu RDL patterns creates a huge electrical field across adjacent RDL lines that results in severe electrolytic migration defects, as observed in FIG. 6A. In FIG. 6B, after going through the disclosed inhibitor CVD coating treatment, as shown in 604, the short circuit time was extended to more than 30 minutes, under 30 V bias, showing that the inhibitor treatment was able to delay the electrochemical migration of the Cu patterns by a factor of more than 30 times.

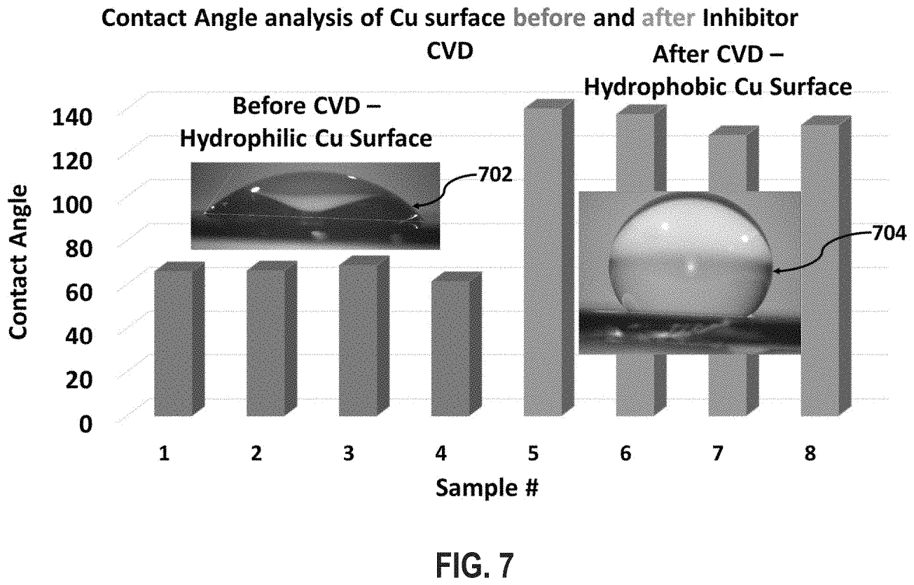

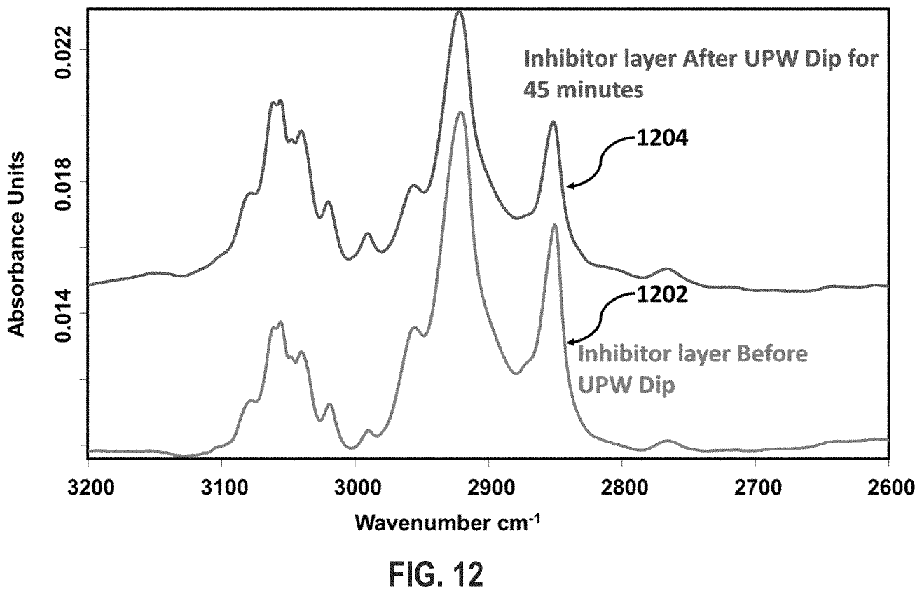

The CVD inhibitor coating may form a hydrophobic layer, with a measured water contact angle of 90-135° (illustrated at 704 of FIG. 7), on top of the Cu metal surface, which can further enhance corrosion protection and capacity. Infrared spectra also revealed the coating layer was unaffected before water immersion (1202 in FIG. 12) and after water immersion (1204 in FIG. 12) demonstrating the hydrophobicity of the CVD deposited protection, as shown in FIG. 12. This hydrophobic nature of the coating may critical as it shields the underlying metal surface from the corrosive contaminants, which are more commonly present in aqueous environments. On the other hand, the Cu metal surface itself without an inhibitor coating showed only a contact angle of 65-70° (illustrated at 702 of FIG. 7), demonstrating its hydrophilic nature.

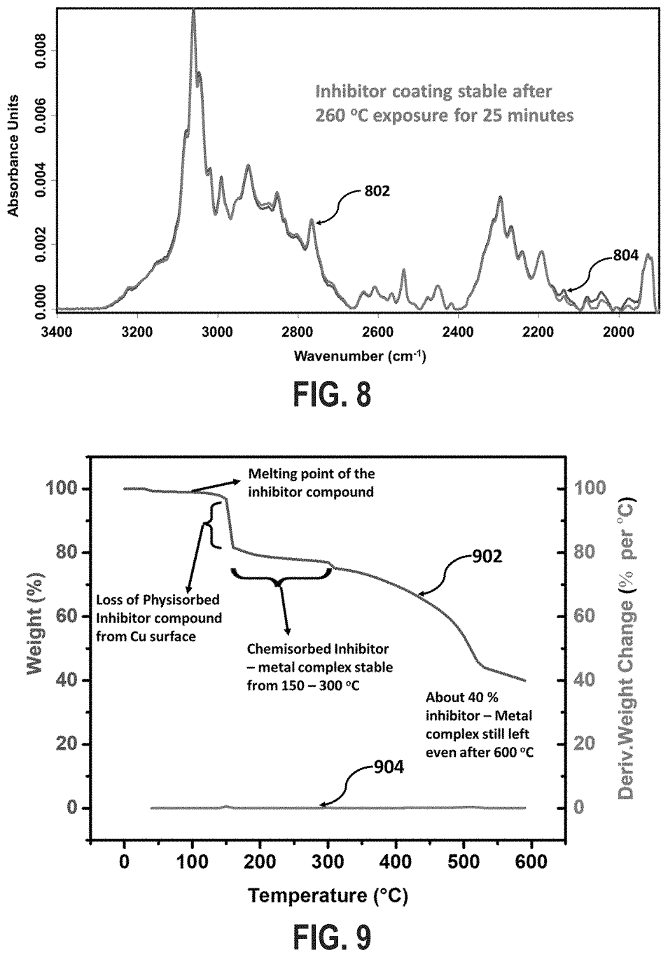

In addition to the factors that are apparent from testing described above with reference to FIGS. 8-12, coatings applied using the above-described processes provide several technical advantages. First, inhibitor coatings applied according to embodiments exhibit excellent thermal stability (e.g., at temperatures >250° C.), enabling the coating process to be utilized across a broad number of applications. In contrast, coatings applied using liquid phase and spray-coating techniques were found to fail at temperatures as low as 150° C. FIG. 8 illustrates the infrared spectra of the CVD inhibitor coating applied to the Cu surface before (e.g., indicated at 802) and after (e.g., indicated at 804) exposure to high temperature annealing (e.g., at temperatures >250° C.). As shown in FIG. 8, no significant change was observed in the infrared spectra and this confirms the thermal stability of the CVD inhibitor coating at higher temperatures. This observation was in line with the Thermal Gravimetric analysis (shown in FIG. 9), which illustrates that the inhibitor layer was unaffected after heating to 300° C. In fact, even a temperature rise to 600° C. did not decompose the bonded inhibitor layer completely off the metal surface (indicated at 902 of FIG. 9)—exhibiting a very high thermal stability.

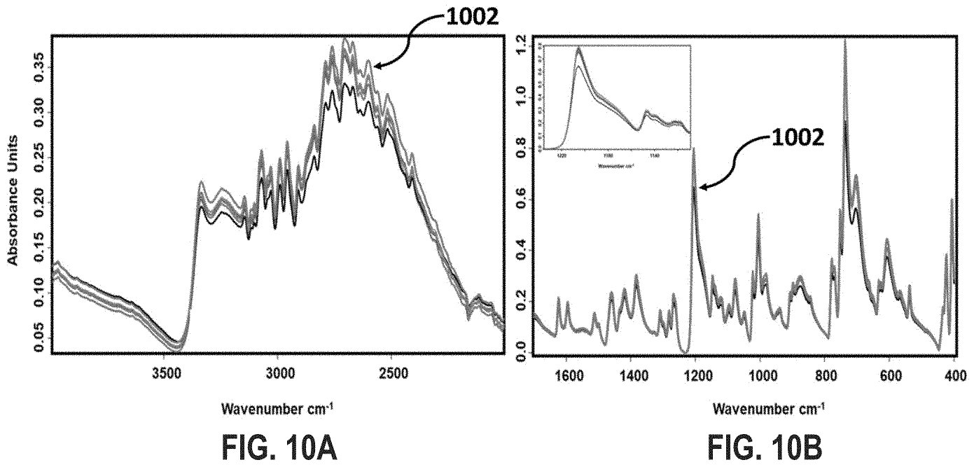

Another technical advantage of using the disclosed methods for applying CVD inhibitor coatings relates to the reusability and recyclability of the selected inhibitor compound (e.g., the inhibitor compound(s) 108 of FIG. 1). Since the CVD deposition temperature was maintained below the decomposition temperature of inhibitor compounds, after each deposition the vapor phases of inhibitor compounds will condense back to the original solid form, available to be reused. Referring to FIGS. 10A and 10B, plots for a series of infrared spectra 1002 of the re-condensed inhibitor compound 108 collected after each CVD coating run are shown. The plotted structural infrared spectra shown in FIGS. 10A and 10B were analyzed after heating the chosen inhibitor compound at 150° C. and re-condensing it to room temperature. The spectra plotted in FIGS. 10A and 10B look very much the same, which indicates there is no structural change in the chosen inhibitor compound after being vaporized and re-condensed during operations in accordance with embodiments. These results demonstrate how the techniques disclosed herein enhance the reusability and recyclability of the inhibitor compounds and increase the efficiency of the coating process (e.g., by reducing waste, etc.).

The above-described coating processes also provide advantages with respect to the costs associated with the coating material. Following application of the inhibitor compound, since the excess vapors may be re-condensed, the re-condensed inhibitor compounds can be reused to apply another inhibitor coating to another metal surface, reducing the overall cost.

The above-described techniques for using CVD deposition to apply inhibitor coatings may also be applicable to other transition metals, such as Fe, Co, Ni, and Zn, which have a similar demonstrated chemical bonding mechanism as the bonding of the inhibitor compound to copper metal.

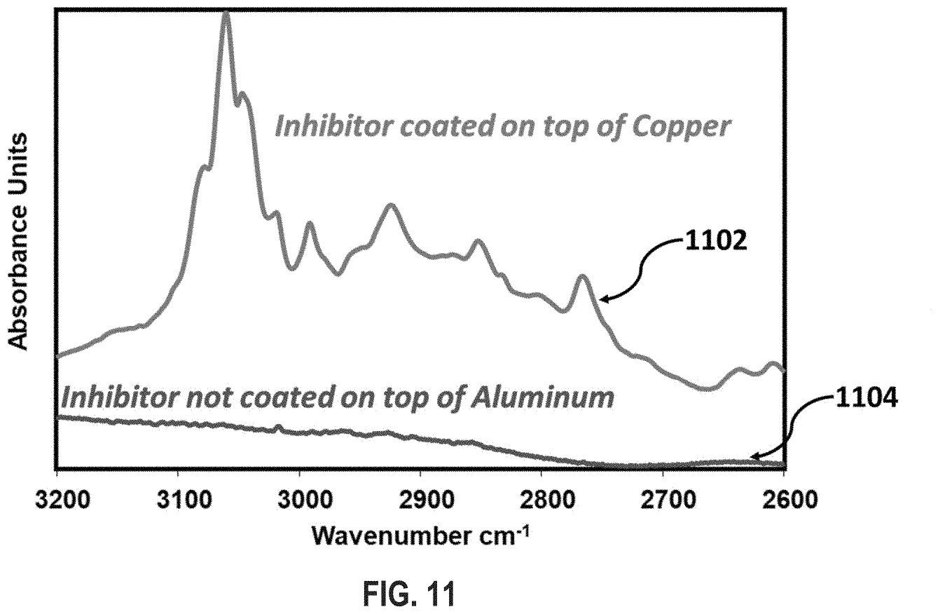

The CVD deposition of the selected inhibitor compound(s) may have high selectivity towards a selected group of targeted transition metals (e.g., Cu, Fe, Co, Ni, and Zn). Referring to FIG. 11, a diagram illustrating plots of infrared spectra observed during testing of metal surfaces according to embodiments of the present disclosure are shown. The infrared spectrum illustrated in FIG. 11 demonstrates the selectivity of the coating process disclosed herein. For example, FIG. 11 shows the comparative test results of IR spectra of copper and aluminum metal surfaces after simultaneous exposure to the coating process disclosed herein. The spectra 1102 shows clearly that the chosen inhibitor compound has a very good bonding to the copper metal surface whereas the spectra 1103 shows no discernable coating on top of aluminum surface, confirming the selectivity of the process disclosed here towards the specific transition metals. It is noted that the high coating selectivity for Cu (shown in FIG. 11) has also been evaluated and observed over other materials, such as dielectric coatings, silicon, Pd, and other metals. This selectivity for applying inhibitor coatings provides a technical advantage that is highly desired and valued in microelectronics scenarios, where the coating process can be used to selectively coat Cu or other selected transition metals in the midst of any other components of a microelectronic device.

The above-described methods for applying an inhibitor coating using CVD may efficiently apply corrosion protection treatment to a large sample batch with various forms and shapes, such as Cu wire bonded devices, flip chips, Cu RDL patterns, etc. Thus, the above-described techniques are suitable for a wide number of applications and provide a versatile technique for applying inhibitor coatings, including application of inhibitor coatings to complex irregularly shaped objects, such as Cu wire-bonded devices, small Cu parts as screws, nuts and pipes used in various applications, or other applications. Due to the advantage of applying the coating while the inhibitor compound(s) is in a vapor phase, crevices, nooks and corners can be coated easily with this type of inhibitor treatment. The possibility of doing a batch operation for the coating of many samples at the same time also reduces the down time or process time for coating a large number of devices at the same time while still applying a uniform coating.

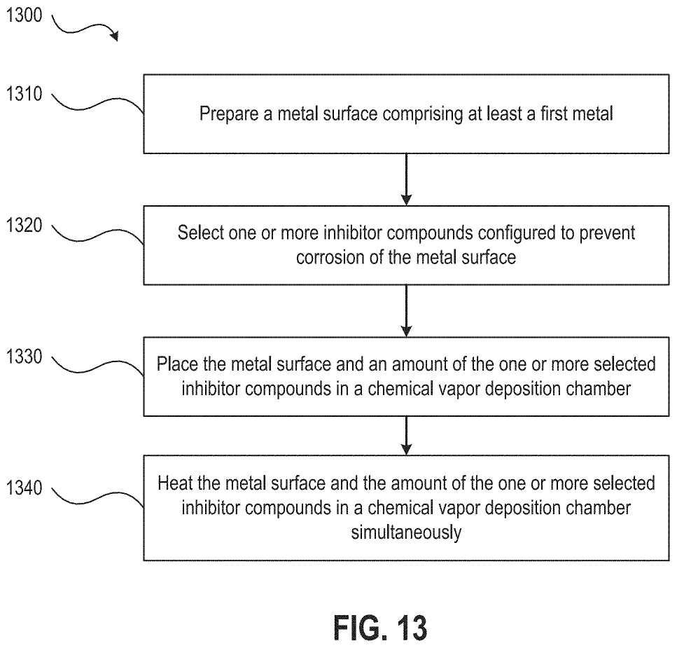

Referring to FIG. 13, a flow diagram illustrating aspects of a method for applying a corrosion inhibitor layer to a metal surface in accordance with the present disclosure is shown as a method 1300. As shown in FIG. 13, the method 1300 includes, at step 1310, preparing the metal surface comprising at least a first metal. Optionally, the metal surface may include a second metal. For example and as explained above, the metal surface may be a Cu RDL pattern. Alternatively, the metal surface may include a first metal and a second metal, such as aluminum pads (second metal) and the preparing may include bonding copper wires (first metal) to the aluminum pads. As explained above, in an aspect the metal surface and the one or more inhibitor compounds may be subjected to the heating within the chemical vapor deposition chamber without pre-treatment (e.g., annealing). In an additional or alternative aspect, the method 1300 may include a pre-treatment step, such as annealing the metal surface prior to placing the amount of the one or more inhibitor compounds in the chemical vapor deposition chamber. When utilized, the annealing pre-treatment step may be performed in the presence of one or more environmental controls. The environment controls may include a gas atmosphere (e.g., hydrogen (H₂) or diazene (N₂H₂)), an acid and base treatment, a plasma treatment, or a combination of these techniques.

At step 1320, the method 1300 includes selecting one or more inhibitor compounds configured to prevent corrosion of the metal surface. The one or more inhibitor compounds may include at least one compound selected from the list consisting of: 5-amino 1,3,4 thiadiazol 2-thiol; 2(2-dihydroxy 5-methyl) Phenyl Benzotriazole; 5-methyl Benzotriazole; Amino tertiary Butyl Pyrazole; Tetrazole; dodecane thiol; azimino toluene; 8-methyl benzotriazole; Cyproconazole; 2-Amino-4-(4-Chlorophenyl)Thiazol; 4-(2-Aminothiazol-4-yl)phenol; 5-Methyl-2-phenyl-2,4-dihydropyrazol-3-one; Diniconazole ((E)-1-(2,4-dichlorophenyl)-4,4-dimethyl2-(1,2,4-triazole-1-yl)-1-pentenyl--ol); 5-(4-Methoxyphenyl)-2-amino1,3,4-thiadiazole; 4-Methyl-5-imidazolecarbaldehyde; 5-(3-Aminophenyl)-tetrazole; 1-H Benzotriazole; 1,2,4 Triazole; 2-mercapto Benzoxazole; 2-mercapto benzimidazole; pyrazole; toly-triazole; 4-Methyl-5-hydroxymethylimidazole; Diniconazole ((E)-1-(2,4-dichlorophenyl)-4,4-dimethyl2-(1,2,4-triazole-1-yl)-1-pentenyl-3-ol); Sulfathiazole; 4-(4-Aminostyryl)-N,N-dimethylaniline; Benzoxazole; 5-(4-Methoxyphenyl)-2-amino1,3,4-thiadiazole; 5-Mercapto-1-phenyl-tetrazole; 5-Mercapto-1-phenyl-tetrazole; Phenyl Methyl Benzotriazole, and other heterocyclic derivatives and substitutes of the compounds mentioned herein.

At step 1330, the method 1300 includes placing the metal surface and an amount of the one or more selected inhibitor compounds in a chemical vapor deposition chamber. At step 1340, the method 1300 includes heating the metal surface and the amount of the one or more selected inhibitor compounds in a chemical vapor deposition chamber simultaneously. As explained above, the heating may be configured to vaporize the one or more selected inhibitor compounds and at least a portion of the vaporized one or more selected inhibitor compounds may bond to the metal surface, which forms or produces a coated metal surface. During formation of the corrosion-inhibiting layer, the portion of the vaporized one or more selected inhibitor compounds may bond to the metal surface via chemical bonding. As demonstrated in the examples above, the corrosion-inhibiting layer may form an irreversible adsorbed layer formed on the metal surface.

During the heating, the temperature within the chemical vapor deposition chamber may be raised to a temperature between 100° C. and 200° C. The method 1300 may include determining a coating time, which may specify a duration or period of time for the heating. The coating time may be determined based at least in part on one or more desired characteristics of the corrosion inhibiting layer. For example, the one or more desired characteristics may include at least a thickness of the corrosion inhibiting layer. It is noted that the coating time is but one exemplary factor that may be used to control the thickness of the applied coating. In some aspects, the thickness of the corrosion inhibiting layer may additionally or alternatively be controlled based on one or more environmental variables used for the chemical vapor deposition process, such as the temperature used for the heating, the amount of the one or more inhibitor compounds placed within the chemical vapor deposition chamber (e.g., larger quantities of the selected one or more inhibitor compounds may result in thicker corrosion inhibiting layers being deposited on the metal surface), and a duration of exposure of the metal surface to the vaporized one or more selected inhibitor compounds (e.g., the coating time described above).

During the heating process and deposition of the corrosion inhibitor layer, the method 1300 may include controlling an ambient environment of the chemical vapor deposition chamber. For example, the ambient environment may be controlled to include at least one gas, such as oxygen, nitrogen, hydrogen, other inert gases, or combinations thereof. The one or more selected inhibitor compounds may be configured to selectively react and deposit on copper and other metal surfaces in the presence of at least one of aluminum, silicon, silicon oxide, silicon nitride, palladium, and gold. Additionally, the corrosion inhibiting layer of the coated metal surface may be configured to prevent corrosion of metals, such as nickel, cobalt, iron, and zinc.

In an aspect, the coated metal surface may be subjected to a post-treatment process subsequent to the heating. The post-treatment processing may include a plasma treatment, which may be performed in the presence of hydrogen, oxygen, and other plasma gases. It is noted that the post-treatment processing may be performed when a pre-treatment is utilized. The post-treatment processing may also include a second annealing step performed at a temperature between 150° C. and 250° C. The second annealing step may be configured to increase the durability of corrosion inhibiting layer applied to the metal surface.

In an aspect, a second portion of the vaporized one or more inhibitor compounds may be recycled by re-condensing the vaporized inhibitor compound subsequent to the heating. The second portion of the vaporized one or more inhibitor compounds may correspond to a portion of the vaporized one or more inhibitor compounds that did not bond to the metal surface. Once the re-condensing is completed, the coated metal surface may be removed from the chemical vapor deposition chamber and a second metal surface may be placed in the chemical vapor deposition chamber. The chemical vapor deposition chamber may then be heated again, vaporizing the one or more inhibitor compounds present within the chamber, which causes a corrosion inhibiting layer to be applied the second metal surface. It is noted that depending on the amount of inhibitor compound reclaimed during the recycling, additional quantities of the one or more inhibitor compounds may be added prior to the heating step. Additionally, if the second metal surface has different materials than the previously treated metal surface, additional types of inhibitor compounds suitable for the different materials (e.g., a different metal or to target a different type of corrosion) may also be added.

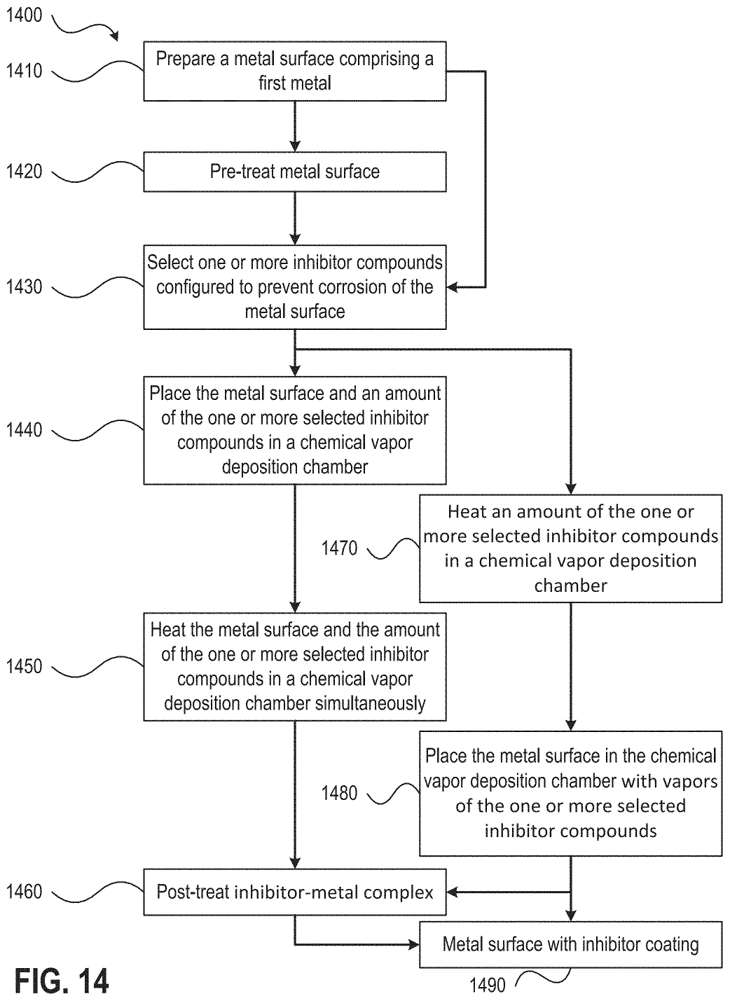

Referring to FIG. 14, a flow diagram illustrating another exemplary method for applying a corrosion inhibitor layer to a metal surface in accordance with the present disclosure is shown as a method 1400. As shown in FIG. 14, the method 1400 includes, at step 1410, preparing the metal surface comprising at least a first metal. It is noted that step 1410 may be performed substantially as described above with reference to step 1310 of FIG. 13 and may include a second metal in some instances. At step 1420, the metal surface may be pretreated. The pretreatment may be performed as described above with reference to FIG. 1, for example. At step 1430, the method 1400 includes selecting one or more inhibitor compounds configured to prevent corrosion of the metal surface. It is noted that step 1430 may be performed substantially as described above with reference to step 1320 of FIG. 13. In an aspect, the pre-treatment step 1420 may be omitted, as indicated by the arrow from step 1410 to step 1430 that bypasses step 1420.

After the one or more inhibitor compounds are selected, the method 1400 may include placing the metal surface and an amount of the one or more selected inhibitor compounds into a chemical vapor deposition chamber, at step 1440, and heating the metal surface and the one or more selected inhibitor compounds within the chemical vapor deposition chamber simultaneously, at step 1450, as described above with reference to steps 1330 and 1340 of FIG. 13. Following the heating at step 1450, the method 1400 may include, at step 1460, applying a post-treatment to the inhibitor-metal complex. As described above, the post-treatment of the coated metal surface may include annealing or other processes. Following completion of step 1460, a metal surface with an inhibitor coating applied in accordance with the present disclosure may be obtained, at step 1490.

In an alternative processing flow, the one or more inhibitor compounds are selected, at step 1430. An amount of the one or more inhibitor compounds may be placed into the chemical vapor deposition chamber and heated, at step 1470. Once the one or more inhibitor compounds have been vaporized, at step 1470, the metal surface may be placed into the chemical vapor deposition chamber, at step 1480. It is noted that step 1480 is performed while the one or more inhibitor compounds are in a vaporized state within the chemical vapor deposition chamber. After a sufficient period of time has passed during which the metal surface is within the chemical vapor deposition chamber while in the presence of the vaporized one or more inhibitor compounds, a metal surface with an inhibitor coating applied in accordance with the present disclosure may be obtained, at step 1490. Alternatively, from step 1480 the method 1400 may proceed to step 1460 where one or more post-treatment processes are performed prior to obtaining, at step 1490, the metal surface with an inhibitor coating applied in accordance with the present disclosure. It is noted that the various options illustrated in the flow of FIG. 14 demonstrate the versatility of the techniques disclosed herein while maintaining the ability to re-condense and re-use the selected one or more inhibitor compounds for further applying inhibitor coatings to other metal surfaces. Further, it is noted that in the methods illustrated in both FIGS. 13 and 14 may provide more than one metal surface into the chemical vapor deposition chamber (e.g., at steps 1330, 1440, or 1480) and may be performed using the system illustrated in FIG. 1.

As described above, the corrosion inhibiting layer applied to the metal surface may be a hydrophobic coating and may be impermeable to water and corrosion agents. The particular corrosion agents for which the corrosion inhibiting layer is impermeable may depend on the particular inhibitor compounds selected. Using the method 1000, the coated metal surface may be thermally stable up to about 300° C., as described above with reference to FIG. 8. As described above with reference to FIGS. 1-14, embodiments of the present disclosure provide improved techniques for applying inhibitor compounds to metal surfaces, such as surfaces of bonded metal devices and other structures which may have complex geometries. Additionally, the coating processes disclosed herein enable single-step application of corrosion inhibiting layers on metal surfaces which result in durable coated surfaces, as illustrated in FIGS. 2-6. The chemical vapor deposition processes disclosed herein may also reduce the costs associated with applying corrosion inhibiting layers to metal surface by enabling unused inhibitor compounds (e.g., portions of the inhibitor compounds that do not bond to the metal surface during heating) to be recycled.

Although embodiments of the present application and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps. Moreover, the scope of the present application is not intended to be limited to the particular embodiments of the process, machine, manufacture, composition of matter, means, methods and steps described in the specification.

1. A method of applying a corrosion inhibitor layer to a metal surface, the method comprising:
preparing the metal surface comprising at least a first metal;
selecting one or more inhibitor compounds configured to prevent corrosion of the metal surface;
placing the metal surface and an amount of the one or more selected inhibitor compounds in a chemical vapor deposition chamber; and
heating the metal surface and the amount of the one or more selected inhibitor compounds in a chemical vapor deposition chamber simultaneously, wherein the heating is configured to vaporize the one or more selected inhibitor compounds, and wherein at least a portion of the vaporized one or more selected inhibitor compounds bonds to the metal surface to form a coated metal surface, the coated metal surface comprising a corrosion inhibiting layer.

2. The method of claim 1, wherein the portion of the vaporized one or more selected inhibitor compounds bonds to the metal surface via chemical bond formation.

3. The method of claim 1, wherein the corrosion-inhibiting layer comprises an irreversible adsorbed layer of inhibitor compound formed on the metal surface.

4. The method of claim 1, wherein the heating comprises raising a temperature within the chemical vapor deposition chamber, and wherein the temperature is raised to between 100° C. and 200° C.

5. The method of claim 1, further comprising determining a coating time, wherein the heating is performed for a period of time corresponding to the coating time, wherein the coating time is determined based at least in part on one or more desired characteristics of the corrosion inhibiting layer, the one or more desired characteristics comprising at least a thickness of the corrosion inhibiting layer.

6. The method of claim 1, further comprising controlling the thickness of the corrosion inhibiting layer based on one or more environmental variables selected from the list consisting of: a temperature of the heating; the amount of the one or more inhibitor compounds placed within the chemical vapor deposition chamber; and a duration of exposure of the metal surface to the vaporized one or more selected inhibitor compounds.

7. The method of claim 1, wherein the metal surface and the one or more inhibitor compounds are subjected to the heating within the chemical vapor deposition chamber without pre-treatment.

8. The method of claim 1, further comprising annealing the metal surface prior to placing the amount of the one or more inhibitor compounds in the chemical vapor deposition chamber.

9. The method of claim 8, wherein the annealing is performed in the presence of a plasma treatment.

10. The method of claim 1, further comprising subjecting the coated metal surface to post-treatment processing subsequent to the heating, wherein the post-treatment processing comprises a treatment selected from the list consisting of: a plasma treatment utilizing at least one of: hydrogen, oxygen, and other plasma gases; and annealing the coated metal surface in the presence of a controlled atmosphere.

11. The method of claim 10, wherein the post-treatment comprises a second annealing performed at a temperature between 150° C.-250° C., and wherein the second annealing is configured to increase the durability of the corrosion inhibiting layer applied to the metal surface.

12. The method of claim 1, further comprising placing a plurality of metal surfaces in the chemical vapor deposition chamber simultaneously with the one or more selected inhibitor compounds to simultaneously coat the plurality of metal surfaces with the corrosion inhibiting layer.

13. The method of claim 1, wherein the one or more inhibitor compounds comprise at least one compound selected from the list consisting of: 5-amino 1,3,4 thiadiazol 2-thiol; 2(2-dihydroxy 5-methyl) Phenyl Benzotriazole; 5-methyl Benzotriazole; Amino tertiary Butyl Pyrazole; Tetrazole; dodecane thiol; azimino toluene; 8-methyl benzotriazole; Cyproconazole; 2-Amino-4-(4-Chlorophenyl)Thiazol; 4-(2-Aminothiazol-4-yl)phenol; 5-Methyl-2-phenyl-2,4-dihydropyrazol-3-one; Diniconazole ((E)-1-(2,4-dichlorophenyl)-4,4-dimethyl2-(1,2,4-triazole-1-yl)-1-pentenyl-3-ol); 5-(4-Methoxyphenyl)-2-amino1,3,4-thiadiazole; 4-Methyl-5-imidazolecarbaldehyde; 5-(3-Aminophenyl)-tetrazole; 1-H Benzotriazole; 1,2,4 Triazole; 2-mercapto Benzoxazole; 2-mercapto benzimidazole; pyrazole; toly-triazole; 4-Methyl-5-hydroxymethylimidazole; Diniconazole ((E)-1-(2,4-dichlorophenyl)-4,4-dimethyl2-(1,2,4-triazole-1-yl)-1-pentenyl-3-ol); Sulfathiazole; 4-(4-Aminostyryl)-N,N-dimethylaniline; Benzoxazole; 5-(4-Methoxyphenyl)-2-amino1,3,4-thiadiazole; 5-Mercapto-1-phenyl-tetrazole; 5-Mercapto-1-phenyl-tetrazole; Phenyl Methyl Benzotriazole, and other heterocyclic derivatives and substitutes of the compounds mentioned herein.

14. The method of claim 1, further comprising:
subsequent to the heating, re-condensing a second portion of the vaporized one or more inhibitor compounds corresponding to a portion of the vaporized one or more inhibitor compounds that did not bond to the metal surface;
removing the metal surface from the chemical vapor deposition chamber;
placing a second metal surface in the chemical vapor deposition chamber; and
heating the second portion of the vaporized one or more inhibitor compounds to apply a corrosion inhibiting layer to the second metal surface.

15. A method of applying a corrosion inhibitor layer to a metal surface, the method comprising:
preparing the metal surface comprising at least a first metal;
selecting one or more inhibitor compounds configured to prevent corrosion of the metal surface;
placing an amount of the one or more selected inhibitor compounds in a chemical vapor deposition chamber;
heating the amount of the one or more selected inhibitor compounds in the chemical vapor deposition chamber to produce inhibitor compound vapors;
placing the metal surface in the chemical vapor deposition chamber in the presence of the inhibitor compound vapors; and
heating the metal surface in the presence of the inhibitor compound vapors, wherein at least a portion of the inhibitor compound vapors bond to the metal surface to form a coated metal surface, the coated metal surface comprising a corrosion inhibiting layer.

16. The method of claim 15, further comprising placing a plurality of metal surfaces in the chemical vapor deposition chamber to simultaneously coat the plurality of metal surfaces with the corrosion inhibiting layer, wherein the plurality of metal surfaces includes the metal surface.

17. The method of claim 15, wherein the portion of the vaporized one or more selected inhibitor compounds bonds to the metal surface via chemical bonding.

18. The method of claim 15, further comprising determining a coating time, wherein the heating is performed for a period of time corresponding to the coating time, and wherein the coating time is determined based at least in part on one or more desired characteristics of the corrosion inhibiting layer, the one or more desired characteristics comprising at least a thickness of the corrosion inhibiting layer.

19. The method of claim 15, wherein the one or more inhibitor compounds comprise at least one compound selected from the list consisting of: 5-amino 1,3,4 thiadiazol 2-thiol; 2(2-dihydroxy 5-methyl) Phenyl Benzotriazole; 5-methyl Benzotriazole; Amino tertiary Butyl Pyrazole; Tetrazole; dodecane thiol; azimino toluene; 8-methyl benzotriazole; Cyproconazole; 2-Amino-4-(4-Chlorophenyl)Thiazol; 4-(2-Aminothiazol-4-yl)phenol; 5-Methyl-2-phenyl-2,4-dihydropyrazol-3-one; Diniconazole ((E)-1-(2,4-dichlorophenyl)-4,4-dimethyl2-(1,2,4-triazole-1-yl)-1-pentenyl-3-ol); 5-(4-Methoxyphenyl)-2-amino1,3,4-thiadiazole; 4-Methyl-5-imidazolecarbaldehyde; 5-(3-Aminophenyl)-tetrazole; 1-H Benzotriazole; 1,2,4 Triazole; 2-mercapto Benzoxazole; 2-mercapto benzimidazole; pyrazole; toly-triazole; 4-Methyl-5-hydroxymethylimidazole; Diniconazole ((E)-1-(2,4-dichlorophenyl)-4,4-dimethyl2-(1,2,4-triazole-1-yl)-1-pentenyl-3-ol); Sulfathiazole; 4-(4-Aminostyryl)-N,N-dimethylaniline; Benzoxazole; 5-(4-Methoxyphenyl)-2-amino1,3,4-thiadiazole; 5-Mercapto-1-phenyl-tetrazole; 5-Mercapto-1-phenyl-tetrazole; Phenyl Methyl Benzotriazole, and other heterocyclic derivatives and substitutes of the compounds mentioned herein.

20. The method of claim 15, further comprising:
subsequent to the heating, re-condensing a second portion of the vaporized one or more inhibitor compounds corresponding to a portion of the vaporized one or more inhibitor compounds that did not bond to the metal surface;
removing the metal surface from the chemical vapor deposition chamber;
placing a second metal surface in the chemical vapor deposition chamber; and
heating the second portion of the vaporized one or more inhibitor compounds to apply a corrosion inhibiting layer to the second metal surface.
